(19) United States
(12) Patent Application Publication
(10) Pub. No.: US 2005/0135073 A1
(43) Pub. Date: Jun. 23, 2005

(54) Electronic assembly and method of disassembly

(75) Inventor: Michael Thorum, Madison, AL (US)

Correspondence Address: SIEMENS CORPORATION;INTELLECTUAL PROPERTY LAW DEPARTMENT, 170 WOOD AVENUE SOUTH, ISELIN, NJ, 08830, US

(73) Assignee: Siemens VDO Automotive Corporation, Auburn Hills, MI (US)

(21) Appl. No.: 10/993,110

(22) Filed: Nov. 19, 2004

Related U.S. Application Data
(60) Provisional application No. 60/524,151, filed on Nov. 21, 2003.

(51) Int. Cl. H05K 5/00; H05K 5/04; H05K 5/06

(52) U.S. Cl. 361/752

(57) ABSTRACT

An electronic assembly includes a housing having an inner compartment that receives an electrical component. The housing includes connector members that secure the electrical component in the inner compartment and provide an electrical connection to the electrical component. The housing includes an opening that corresponds in position to a surface portion of the electrical component. The opening provides access for a repair tool to be inserted though the housing and press on the surface portion of the electrical component for the purpose of removing the electrical component from the connector members. The electronic assembly and repair tool therefore avoid laborious and potentially damaging disassembly methods while providing a simple design that is easily disassembled.

### RELATED APPLICATION

The application claims priority to U.S. Provisional Application No. 60/524,151, filed on Nov. 21, 2003.

### BACKGROUND OF THE INVENTION

This invention relates to an electronic assembly and, more particularly, to an electronic assembly and repair tool for easily disassembling an electrical component from the electronic assembly without damaging the electrical component.

Motorized vehicles typically include a variety of electronically controlled vehicle systems, such as a transmission system. Electronic assemblies used to control or communicate with the vehicle systems usually include an electrical component, for example a circuit board, that is enclosed in a plastic or metal housing. The housing protects the electrical component from becoming damaged during installation, handling, and/or operation of the electrical component.

Conventionally, the electrical component is press-fit onto electrical connector pins in the housing. The electrical connector pins extend through the housing and into a harness connector on the exterior of the housing. The electrical connector pins provide an electrical connection between the electrical component and harness connector. The harness connector typically receives a vehicle wire harness, which electrically connects the electrical component with other electronic assemblies of the motorized vehicle.

Disadvantageously, these typical electronic assemblies are not designed for disassembly. There is little or no clearance gap between the electrical component and the housing, making removal of the electrical component from the housing difficult without damaging the electrical component. For example, the housing may be cut with a cutting device or the electrical component pried loose from the electrical connector pins to remove the electrical component from the housing. The housing may be destroyed during such disassembly methods and there is risk of damaging the electrical component. These disassembly methods may also be laborious, time consuming and expensive.

Accordingly, there is a need for an electronic assembly design that is easy to disassemble. This invention addresses this need and provides enhanced capabilities while avoiding the shortcomings and drawbacks of the prior art.

### SUMMARY OF THE INVENTION

An exemplary electronic assembly includes a housing having an inner compartment that receives an electrical component. The housing includes connector members that secure the electrical component in the inner compartment and provide an electrical connection to the electrical component. The housing includes an opening that corresponds in position to a surface portion of the electrical component. The opening provides access for a repair tool to be inserted though the housing to press on the surface portion of the electrical component for the purpose of removing the electrical component from the connector members.

One example repair tool includes a base portion and an extended portion. The extended portion corresponds in shape to the opening in the housing of the electronic assembly. The base portion includes two opposing cavities that receive the connector members when the repair tool is inserted into the opening to disassemble the electronic assembly.

Another example electronic assembly includes a housing having a plurality of openings for disassembling the electrical component from the housing. The electrical component includes a plurality of surface portions and each opening corresponds to one of the plurality of surface portions such that electrical surface devices on the electrical component are not damaged during the disassembly. An example corresponding repair tool includes a plurality of extended portions that respectively correspond to the plurality of openings in the housing.

The electronic assembly and repair tool therefore avoid laborious and potentially damaging disassembly methods while providing a simple design that is easily disassembled.

### BRIEF DESCRIPTION OF THE DRAWINGS

The various features and advantages of this invention will become apparent to those skilled in the art from the following detailed description of the currently preferred embodiment. The drawings that accompany the detailed description can be briefly described as follows.

FIG. 1 illustrates a schematic exploded view of an electronic assembly;

FIG. 2 illustrates a schematic cross-sectional assembled view of the electronic assembly of FIG. 1;

FIG. 3 illustrates one example repair tool for disassembling the electronic assembly of FIG. 1;

FIG. 4 illustrates a magnified view of the repair tool in a repair position;

FIG. 5 illustrates disassembly of the circuit board from the plurality of connector members;

FIG. 6 illustrates another example of disassembling the circuit board;

FIG. 7 is a perspective view of another example electronic assembly; and

FIG. 8 illustrates a perspective view of another example repair tool.

### DETAILED DESCRIPTION OF THE PREFERRED EMBODIMENT

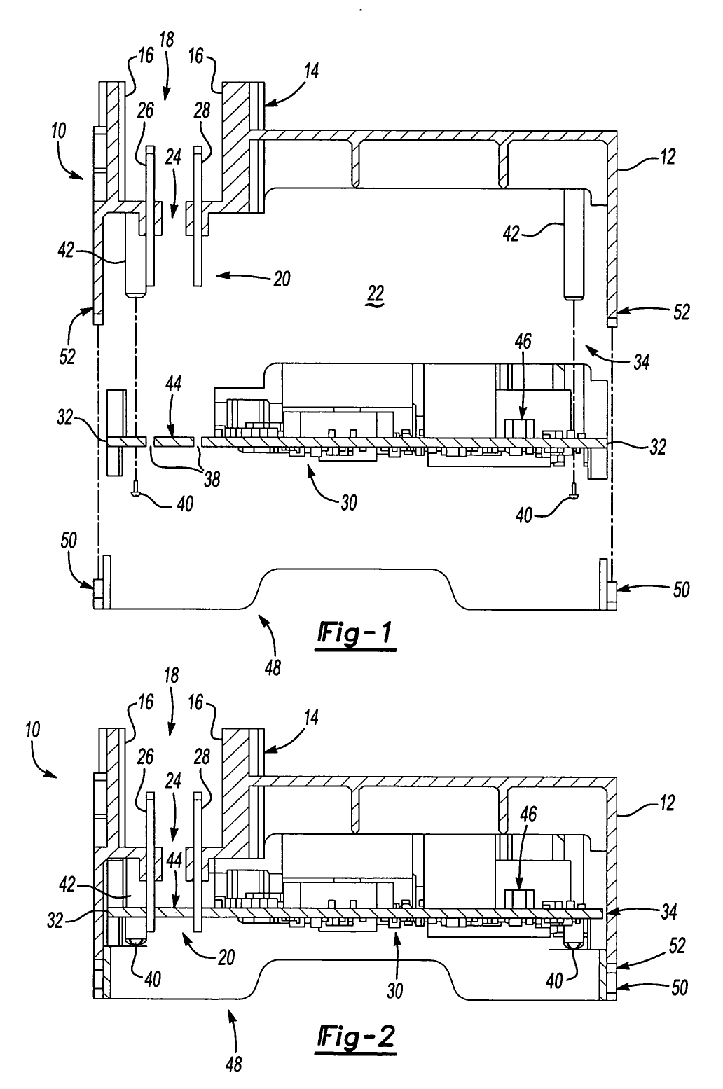

FIG. 1 illustrates a schematic exploded view of an electronic assembly 10, for example a transfer case module for controlling operation of a motorized vehicle transmission. The electronic assembly 10 includes a housing 12, which for example is fabricated from a molded plastic or a metal. The housing 12 includes a connector header 14. In the example shown, the connector header 14 includes walls 16 that form a female boss 18 for attachment to a corresponding male electrical harness connector (not shown). Although the housing 12 and connector header 14 are shown as one integrated piece, the connector header 14 may also be a separate piece from the housing 12. This may provide the benefit of forming the connector header 14 out of a plastic and the housing out of a different material, such as metal, to function as an electromagnetic shield.

The connector header 14 includes a plurality of connector members 20, for example known electrical press-fit pins. The plurality of connector members 20 extend from the female boss 18, through the housing 12, and into an inner compartment 22 of the housing 12. In one example, the plurality of connector members 20 are insert-molded into the connector header 14. In another example, the plurality of connector members 20 are removably press-fit into molded-in holes in the connector header 14.

The connector header 14 of the housing 12 also includes an opening 24, such as an elongated slot. In one example, the opening 24 is located between two connector members 26, 28 of the plurality of connector members 20. The opening 24 provides access to the inner compartment 22 for disassembly of the electronic assembly 10, which will be described in more detail below.

An electrical component, such as a circuit board 30 or other electrical component, is received in the inner compartment 22 during an assembly process. The circuit board 30 includes outer peripheral edges 32. A clearance gap 34 of less than 5 millimeters, and preferably about 0.5 millimeters, remains between the outer peripheral edges 32 and walls 36 of the housing 12 when the circuit board 30 is secured in the inner compartment 22. This relatively small clearance gap 34 generally makes it difficult to disassemble the circuit board 30 from the housing 12 using a tool, such as a screwdriver or even a finger, because the tool does not easily fit into the clearance gap 34 to pry the circuit board 30 from the housing 12.

The plurality of connector members 20 are received into corresponding attachment openings 38 on the circuit board 30 and form a frictional-fit between the plurality of connector members 20 and the corresponding attachment openings 38, such as metal-plated-through-holes. The terminology “frictional-fit” as used herein refers broadly to an interference connection wherein the interference between connecting portions secures the portions together.

The frictional-fit secures the circuit board 30 in the inner compartment 22 of the housing 12. In one example, the plurality of connector members 20 are electrically conductive and provide an electrical connection between the circuit board 30 and the corresponding male electrical harness connector. The circuit board 30 is further secured in the inner compartment 22 with fasteners 40 that extend through the circuit board 30 and into corresponding fastener bosses 42 in the inner compartment 22.

The circuit board 30 also includes a surface portion 44 that corresponds in position to the opening 24. In one example, the circuit board 30 includes a plurality of electrical circuit devices 46, such as capacitors, resistors, and/or other devices, but the surface portion 44 of the circuit board 30 does not include electrical circuit devices 46 (sometimes referred to as a keep-out zone). This may provide the benefit of disassembling the circuit board 30 from the housing 12 without damaging the electrical circuit devices 46, as will be explained in more detail below. Although only one surface portion 44 is shown in this example, the circuit board 30 may include additional surface portions 44 in other examples having more than one opening 24.

A cover 48 is received onto the housing 12 to enclose the circuit board 30 in the inner compartment 22. The cover 48 includes snap-fit portions 50 that secure the cover 48 to corresponding housing snap-fit portions 52 of the housing 12 to form the assembled electronic assembly 10, as illustrated in FIG. 2. Alternatively, the cover 48 may be secured to the housing 12 using a fastener or other method of attachment.

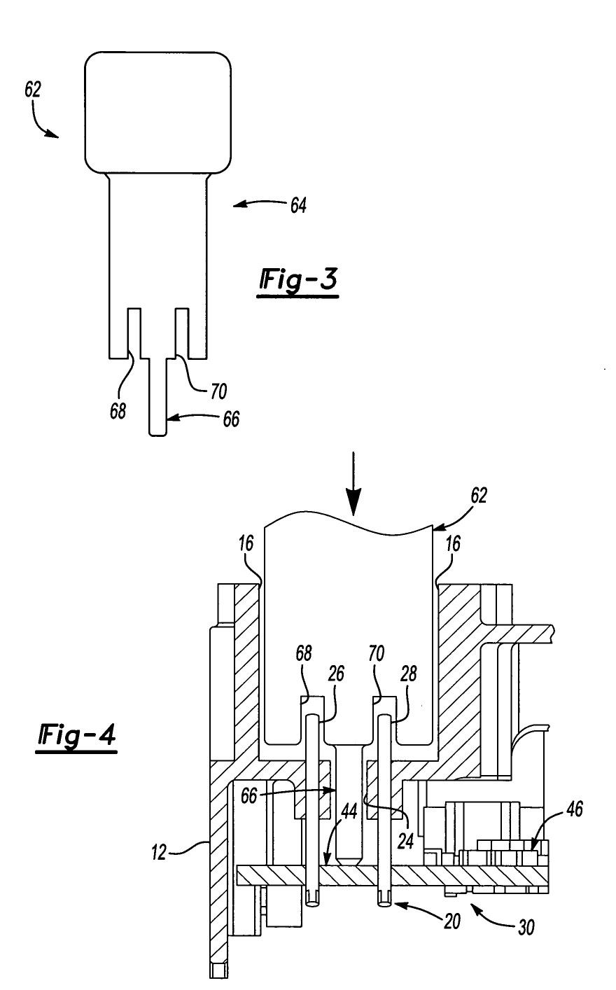

One example method of disassembling the assembled electronic assembly 10 utilizes a repair tool 62, as illustrated in the schematic cross-sectional view of FIG. 3. The repair tool 62 includes a base portion 64 and an extended portion 66 connected to the base portion 64. In one example, a cross-section of the extended portion 66 corresponds to a cross-section of the opening 24 such that the extended portion 66 fits through the opening 24 and is able to contact the surface portion 44 of the circuit board 30.

The base portion 64 of the repair tool 62 also includes two opposing cavities 68, 70. The two opposing cavities 68, 70 extend into the base portion 64 and receive the plurality of connector members 20 when the repair tool 62 is inserted into the opening 24 to disassemble the electronic assembly 10. In the example shown, the opposing cavities 68, 70 are generally rectangular-shaped, however, circular or other shapes may also be utilized.

FIG. 4 illustrates a magnified view of the repair tool 62 in a repair position, after the cover 48 and fasteners 40 are removed from the housing 12. The extended portion 66 is at least partially received into the opening 24, which is generally aligned with the surface portion 44 of the circuit board 30. The extended portion 66 contacts the surface portion 44 of the circuit board 30.

As the extended portion 66 is received into the opening 24, the two opposing cavities 68, 70 at least partially receive the plurality of connector members 20. This may provide the advantage of maintaining an elongated shape of the plurality of connector members 20 by avoiding stressful contact between the plurality of connector members 20 and the base portion 64, which could deform, bend, or loosen the plurality of connector members 20. Alternatively, a similar benefit may be gained without the two opposing cavities 68, 70 if the extended portion 66 is made long enough to contact the circuit board 30 without the base portion 64 contacting the plurality of connector members 20.

Once the extended portion 66 contacts the surface portion 44, a removal force is applied to the repair tool 62. Since the surface portion 44 does not include electrical circuit devices 46, the electrical circuit devices 46 on the circuit board 30 are not subjected to the potentially damaging removal force. This feature may provide the benefit of preventing damage to the electrical circuit devices 46 during disassembly of the circuit board 30.

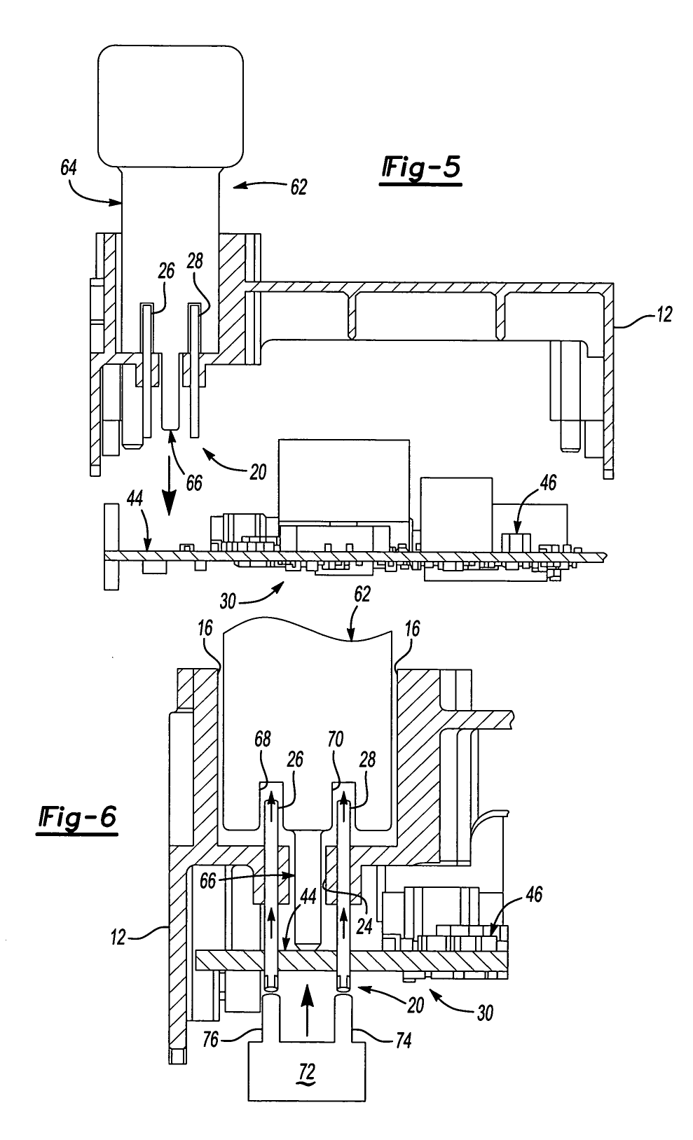

The removal force is generally applied in a direction opposite a direction that the circuit board was received onto the plurality of connector members 20 to overcome the frictional-fit between the plurality of connector members 20 and the circuit board 30. Generally, the removal force moves the circuit board 30 relative to the plurality of connector members 20. The removal force may be applied manually, such as by an operator, or automatically using a known automated machine. When the removal force overcomes the frictional-fit, the circuit board 30 detaches from the plurality of connector members 20 and slides out of the housing 12, as illustrated in FIG. 5.

Utilizing the repair tool 62 in the above disassembly method may provide the benefit of avoiding having to pry the circuit board 30 from the housing 12 or having to cut the housing 12 to free the circuit board 30 from the plurality of connector members 20. The electronic assembly 10 and repair tool 62 therefore provide a simple design that is easily disassembled.

In one example, arranging the opening 24 between at least two connector members 26, 28 of the plurality of connector members 20 may also provide the benefit of limiting stress on the plurality of connector members 20 during the time when the circuit board 30 is pushed off of the connector members 20 using the repair tool 62 (reducing a risk of damaging the connector members 20). That is, stress on the plurality of connector members 20 may be more evenly distributed among the plurality of connector members 20 rather than generally concentrated on only one or a few connector members 20.

FIG. 6 is another example of disassembling the circuit board 30 using the repair tool 62. In this example, the repair tool 62 includes a second member 72 with pronged portions 74, 76 that exert a removal force on the connector members 26, 28. The connector members 26, 28 are removably press-fit into the connector header 14 and move relative to the circuit board 30 and housing 12. The connector members 26, 28 move into the two opposing cavities 68, 70. The pronged portions 74, 76 push the connector members 26, 28 through the attachment openings 38 in the circuit board 30 to overcome the frictional-fit between the circuit board 30 and the connector members 26, 28. The circuit board is then able to slide out of the housing 12, as illustrated in FIG. 5.

Generally, the repair tool 62 is static and the second member 72 moves to exert the removal force, which results in the connector members 26, 28 moving relative to the circuit board 30. However, in other examples, the both the repair tool 62 and second member 72 move to respectively exert the removal force on the circuit board 30 and the connector members 26, 28 and the circuit board 30 and the connector members 26, 28 move relative to each other.

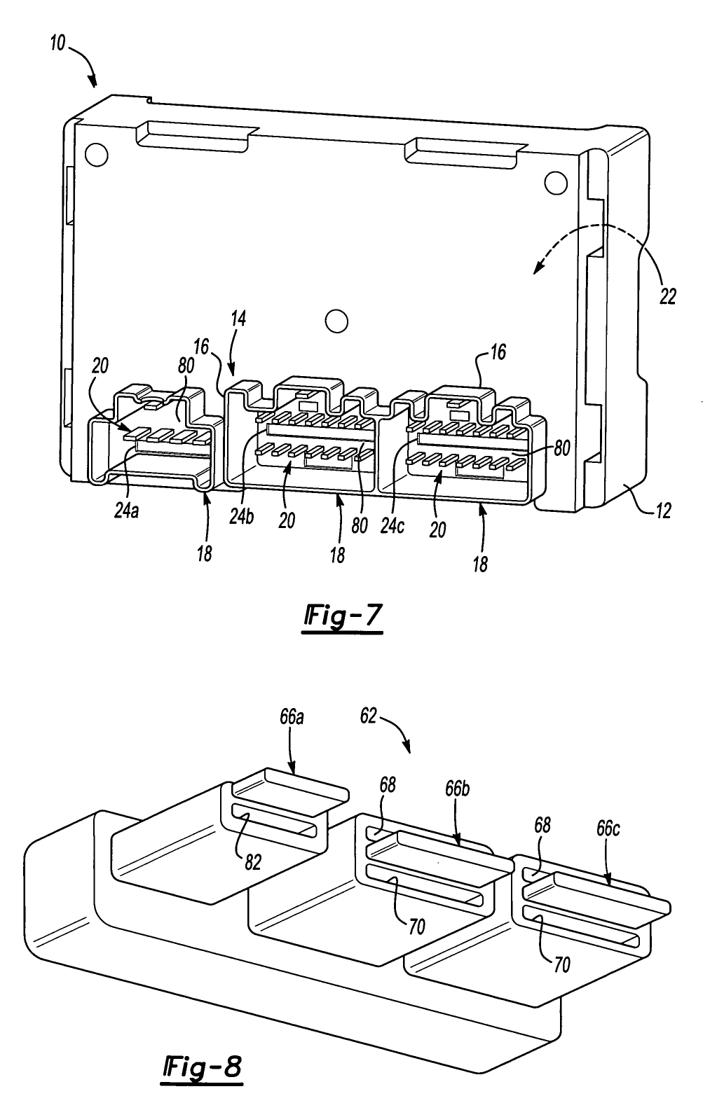

FIG. 7 is a perspective view of another example electronic assembly 10 configuration. The electronic assembly 10 includes a housing 12 having a connector header 14. The connector header 14 includes walls 16 that form a plurality of female bosses 18. Each of the plurality of female bosses 18 includes a plurality of connector members 20 that are arranged in rows 80. Each of the plurality of female bosses 18 also includes an opening 24a, 24b, 24c for disassembling an electrical component from the inner compartment 22 of the housing 12.

FIG. 8 illustrates a perspective view of another example repair tool 62. The repair tool 62 corresponds to the electronic assembly 10 of FIG. 6 and includes a plurality of extended portions 66a, 66b, 66c that correspond respectively to the openings 24a, 24b, 24c in the plurality of female bosses 18 of the electronic assembly 10 of FIG. 6. Two of the extended portions 66b, 66c each include opposing cavities 68, 70 and the extended portion 66a includes a single cavity 82. The opposing cavities 68, 70 and single cavity 82 receive the plurality of connector members 20 adjacent to the respective corresponding openings 24a, 24b, 24c during a disassembly process that is similar to that shown in FIG. 4.

Although a preferred embodiment of this invention has been disclosed, a worker of ordinary skill in this art would recognize that certain modifications would come within the scope of this invention. For that reason, the following claims should be studied to determine the true scope and content of this invention.

1. An electronic assembly comprising:
a housing including an inner compartment;
an electrical component that is receivable into a secured position in said inner compartment, said electrical component including a surface portion that receives a removal force when said electrical component is removed from said secured position;
an opening in said housing, said opening corresponding in position to said surface portion.

2. The assembly as recited in claim 1, wherein said opening is generally aligned with said surface portion.

3. The assembly as recited in claim 1, wherein said housing comprises a connector member and said connector member secures said electrical component in said secured position.

4. The assembly as recited in claim 3, wherein said connector member is one of a plurality of connector members that secure said electrical component in said secured position.

5. The assembly as recited in claim 4, wherein said opening is located between at least two connector members of said plurality of connector members.

6. The assembly as recited in claim 5, wherein at least some of said plurality of connector members are configured in two rows and said opening is located between said two rows.

7. The assembly as recited in claim 1, wherein said electrical component comprises a circuit board having a plurality of electrical circuit devices and said surface portion of said circuit board generally does not include electrical circuit devices.

8. The assembly as recited in claim 7, wherein said circuit board includes peripheral outer edges and said inner compartment includes inner walls, and said peripheral outer edges and said inner walls form a gap when said electrical component is in said secured position, and said gap is less than 5 millimeters.

9. The assembly as recited in claim 8, wherein said gap is about 0.5 millimeters or less.

10. The assembly as recited in claim 1, wherein said opening includes a cross-sectional shape that corresponds to a repair tool for removing said electrical component from said secured position.

11. A method of dissembling an electrical component from a connector member in a housing of an electrical assembly comprising the step:
moving at least one of the electrical component or the connector member relative to the other to overcome a frictional-fit between the electrical component and the connector member.

12. The method as recited in claim 11, including extending at least a portion of a repair tool through an opening in the housing, using the repair tool to exert a removal force on the electrical component and move the electrical component relative to the connector member to overcome the frictional-fit.

13. The method as recited in claim 12, including exerting the removal force on a portion of the electrical component that does not include electrical devices.

14. The method as recited in claim 11, including using a repair tool to exert a removal force on the connector member and move the connector member relative to the electrical component to overcome the frictional-fit.

15. The method as recited in claim 11, including using a repair tool to exert a removal force on the electrical component and the connector member to respectively move the electrical member and the connector member relative to each other.

16. A repair tool for disassembling an electronic assembly, the electronic assembly including a housing with an electrical component removably secured in an inner compartment of the housing, and an opening in the housing for receiving the repair tool, the repair tool comprising:
a base portion; and
an extended portion connected to said base portion, said extended portion corresponding in shape to the opening in the housing, and said extended portion having at least a repair position wherein said extended portion extends at least partially into the opening.

17. The repair tool as recited in claim 16, wherein said extended portion includes an extended portion cross-sectional shape, and said extended portion cross-sectional shape corresponds to a cross-sectional shape of the opening.

18. The repair tool as recited in claim 16, wherein the electrical assembly includes at least one electrical connector that extends from a surface adjacent to the opening, and said base portion includes a cavity located adjacent to the extended portion, said cavity receiving the electrical connectors when the extended portion is in the repair position.

19. The repair tool as recited in claim 16, wherein said extended portion is one of a plurality of extended portions connected to said base portion, and each of said plurality of extended portions corresponds to one of a plurality of openings in the housing.
